(19) United States
(12) Patent Application Publication
(10) Pub. No.: US 2024/0413162 A1
(43) Pub. Date: Dec. 12, 2024

(54) CAVITY WITH BOTTOM HAVING DIELECTRIC LAYER PORTION OVER GATE BODY WITHOUT ETCH STOP LAYER AND RELATED METHOD

(71) Applicant: GlobalFoundries Singapore Pte. Ltd., Singapore (SG)

(72) Inventors: Kah Wee Gan, Singapore (SG); Xuesong Rao, Singapore (SG); Wensheng Deng, Singapore (SG); Kemao Lin, Singapore (SG)

(21) Appl. No.: 18/332,147

(22) Filed: Jun. 9, 2023

(51) Int. Cl. H01L 27/12; H01L 21/768; H01L 23/528

(52) U.S. Cl. CPC H01L 27/1203; H01L 21/7682; H01L 21/76895; H01L 23/528

(57) ABSTRACT

A semiconductor device includes a transistor including source/drain regions and a gate, the gate having a gate body. An etch stop layer is over the source/drain regions but not over the gate body. An interconnect layer is over the transistor and includes a dielectric layer. A cavity extends partially through the interconnect layer above the gate, and a portion of the dielectric layer is over the gate body and defines a bottom of the cavity. The cavity provides a mechanism to reduce both on-resistance and off-capacitance for applications such as radio frequency switches.

### BACKGROUND

The present disclosure relates to semiconductor devices, and more specifically, to a semiconductor device with a cavity, such as an air gap, with a bottom defined by a portion of a dielectric layer over a gate body without an etch stop layer. A method of forming the semiconductor device is also provided.

Radio frequency (RF) switches are widely used in telecommunications equipment such as smartphones to route high frequency telecommunications signals through transmission paths.

For instance, RF switches are commonly used in smartphones to allow use with different digital wireless technology standards used in different geographies. Current RF switches are generally fabricated using semiconductor-on-insulator (SOI) substrates. SOI substrates typically use a layered silicon-insulator-silicon substrate in place of a more conventional silicon substrate (bulk substrate). SOI-based devices differ from conventional silicon-built devices in that the silicon junction is above an electrical insulator, typically silicon dioxide or (less commonly) sapphire.

One challenge with RF switches formed in SOI substrates is controlling two competing parameters: on-resistance (Rₒₙ) which is the resistance of the switch when power is switched on, and off-state capacitance (C_{off}) which indicates the amount of cross-talk or noise that may occur within the system, i.e., the amount transmitted signals on one circuit creates an undesired effect on another circuit. Rₒₙ is preferred to be as low as possible when the RF switch is on to reduce the power consumption, and C_{off} should be minimized to reduce undesired coupling noise. In conventional semiconductor manufacturing processes, lowering either Rₒₙ or C_{off} results in the opposite effect in the other parameter.

### SUMMARY

A first aspect of the disclosure is directed to a semiconductor device, comprising: a substrate; a transistor including source/drain regions in the substrate and a gate, the gate having a gate body; an etch stop layer over the source/drain regions but not over the gate body; an interconnect layer over the transistor, the interconnect layer including a dielectric layer; and a cavity extending partially through the interconnect layer above the gate, wherein a portion of the dielectric layer is over the gate body and defines a bottom of the cavity.

A second aspect of the disclosure includes a radio frequency semiconductor-on-insulator (RFSOI) switch, comprising: a transistor including source/drain regions in a semiconductor-on-insulator (SOI) layer of an SOI substrate and a gate over the SOI layer, the gate having a gate body; an etch stop layer over the source/drain regions but not over the gate body; an interconnect layer over the transistor, the interconnect layer including a dielectric layer; and an air gap extending partially through the interconnect layer above the gate, wherein a portion of the dielectric layer is over the gate body and defines a bottom of the air gap.

A third aspect of the disclosure is related to a method comprising: forming an interconnect layer over a transistor including an etch stop layer over source/drain regions of the transistor but not over a gate body of a gate of the transistor, the interconnect layer including a dielectric layer over the transistor; and forming an opening into the dielectric layer, leaving a portion of the dielectric layer over the gate body; and forming a cavity over the gate by depositing a capping layer to seal the opening.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a preliminary structure for a method according to embodiments of the disclosure;

FIG. 2 shows an enlarged cross-sectional view of an illustrative transistor;

FIG. 3 shows a cross-sectional view of etching to remove an etch stop layer over a gate body using a first cavity mask having a cavity pattern therein according to embodiments of a method of the disclosure;

FIG. 4 shows a cross-sectional view of forming an interconnect layer according to embodiments of the disclosure;

FIG. 5 shows a cross-sectional view of forming a second cavity mask having the cavity pattern according to embodiments of a method of the disclosure;

FIG. 6 shows a cross-sectional view of etching an opening for a cavity according to embodiments of a method of the disclosure;

FIG. 7 shows a cross-sectional view of recessing an opening according to other embodiments of the disclosure;

FIG. 8 shows a cross-sectional view of removing a cavity mask according to embodiments of the disclosure;

FIG. 9 shows a cross-sectional view of a semiconductor device such as a radio frequency SOI switch with a cavity over a transistor gate thereof according to embodiments of the disclosure;

FIG. 10 shows a cross-sectional view of a semiconductor device such as a radio frequency SOI switch with a cavity over a transistor gate thereof according to other embodiments of the disclosure;

FIG. 11 shows an enlarged cross-sectional view of any one of the transistors in FIGS. 9 and 10; and

FIG. 12 shows a top-down view of a semiconductor device illustrating one example of a laterally elongated layout of a cavity according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on,” “directly contacting” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The present disclosure relates to methods of forming semiconductor devices including a cavity, such as an air gap, over a gate for reducing the capacitance between the gate and adjacent wires, contacts, and vias used to contact the source and drain of the transistor. This capacitance reduction may decrease the off-state capacitance of the transistor when it is used in in such applications as radio frequency (RF) switches in semiconductor-on-insulator (SOI) substrates or bulk (non-SOI) substrates. Use of a cavity over a gate according to the various embodiments of the disclosure provides a mechanism to reduce off-capacitance of any device using it by controlling one of the main contributors of intrinsic field effect transistor (FET) capacitance: the effective dielectric constant of the contact or local interconnect layer and the first metal layer. While the teachings of the disclosure will be described with regard to an SOI substrate and relative to an RF switch, it will be understood that the embodiments can be applied to various alternative semiconductor devices such as but not limited to low noise amplifiers (LNA) and power amplifiers. Further, the teachings may be applied to different substrates, such as a bulk substrate.

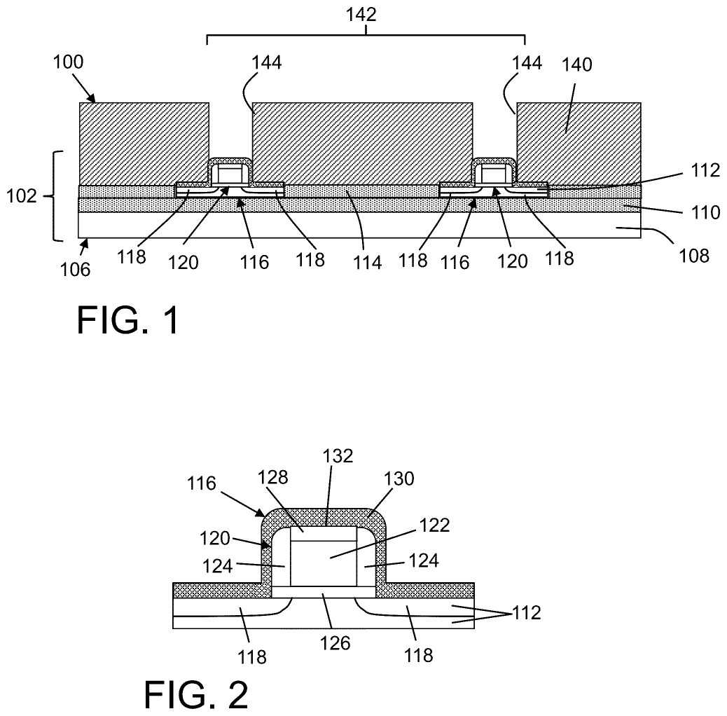

Referring to FIGS. 1-11, cross-sectional views of a method of forming a cavity, such as an air gap, for a semiconductor device according to embodiments of the disclosure are illustrated. FIGS. 1-4 show forming an interconnect layer over a transistor including an etch stop layer over source/drain regions of the transistor but not over a gate body of a gate of the transistor, the interconnect layer including a dielectric layer over the transistor. More particularly, FIGS. 1-3 show using a first mask having a cavity pattern, removing an etch stop layer over a gate body of a gate of a transistor with the etch stop layer remaining over the source/drain regions of the transistor. FIG. 1 shows a preliminary structure 100 after formation of a device layer 102. Device layer 102 is illustrated as including a semiconductor-on-insulator (SOI) substrate 106 including a semiconductor substrate 108 with an insulator layer 110 thereover and a semiconductor-on-insulator (SOI) layer 112 thereover. Substrate 108 and SOI layer 112 may include any semiconductor material described herein. Furthermore, a portion or entire semiconductor substrate 108 and/or SOI layer 112 may be strained. For example, SOI layer 112 may be strained. SOI layer 112 may be segmented by shallow trench isolations (STI) 114. Insulator layer 110 may include any appropriate dielectric material for the application desired, e.g., silicon oxide (SiOₓ) or (less commonly) sapphire. Insulator layer 110 and/or STI 114 may also include the same material, such as silicon dioxide or any other interlayer dielectric material described herein.

Device layer 102 also includes a number of transistors 116 formed therein. (In the drawings, two transistors 116 and respective cavities 230 are shown for clarity of illustration—any number of transistors and cavities can be used). Each transistor 116 may include any now known or later developed transistor structure such as doped source/drain regions 118 in SOI layer 112 having a transistor gate 120 thereover and therebetween. FIG. 2 shows an enlarged cross-sectional view of an illustrative transistor 116 and transistor gate 120. Each gate 120 may include, among other structures, a gate body 122 of polysilicon or a metal gate conductor (commonly referred to collectively as “PC”), sidewall spacers 124 adjacent gate body 122, a gate dielectric 126 under gate body 122, a silicide layer 128 over gate body 122 (i.e., a silicon-metal alloy), and an etch stop layer 130 over silicide layer 128 and/or spacers 124. Sidewall pacers 124 may include any now known or later developed spacer material such as silicon nitride (Si₃N₄), and gate dielectric 126 may include any now known or later developed gate dielectric material such as: hafnium silicate (HfSiO), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material or any combination of these materials. Etch stop layer 130 may include any now known or later developed material, such as silicon nitride, to stop a particular etching process. Etch stop layer 130 is laterally adjacent to sidewall spacer 124. Silicide layer 128 may include any now known or later developed silicide material, e.g., titanium, nickel, cobalt, etc. Silicide layer 128 includes an upper surface 132. As understood, each gate 120 may run into, out of, or across the page as illustrated. Each transistor 116 may be formed using can be formed using any now known or later developed semiconductor fabrication techniques, e.g., material deposition, photolithographic patterning and etching, doping, etc. As such techniques are well understood those skilled in the art, no further details are necessary.

Returning to FIG. 1, a first mask 140 having an air gap pattern 142 therein is formed. First mask 140 may be referred to as an “air gap mask.” Air gap pattern 142 may include openings 144 with a pattern to form air gaps where desired. Air gap pattern 142 exposes a portion over gates 120 of transistors 116 in device layer 102. Mask 140 may include any now known or later developed masking material. The term “mask” may be given to a layer of material which is applied over an underlying layer of material, and patterned to have openings, so that the underlying layer can be processed where there are openings. Common masking materials are photoresist (resist) and nitride. Nitride is usually considered to be a “hard mask.” Mask may include a developable organic planarization layer (OPL) on the layer to be etched, a developable anti-reflective coating (ARC) layer on the developable OPL, and a photoresist mask layer on the developable ARC layer. Masks may be removed using any known removal process appropriate for the mask material, e.g., a wet etch for hard nitride mask or an ashing process (oxygen dry strip process) for a soft resist-based mask. Mask 140 is patterned and etched in a conventional fashion to create air gap pattern 142 therein. In one embodiment, transistor gate 120 width is approximately 200 nanometers (nm) and openings in first mask 140 may have a size of approximately 120 nm to 140 nm. These widths could scale with larger and smaller channel transistor width or with larger or smaller contact 180 (FIG. 4) and wire 182 (FIG. 4) width.

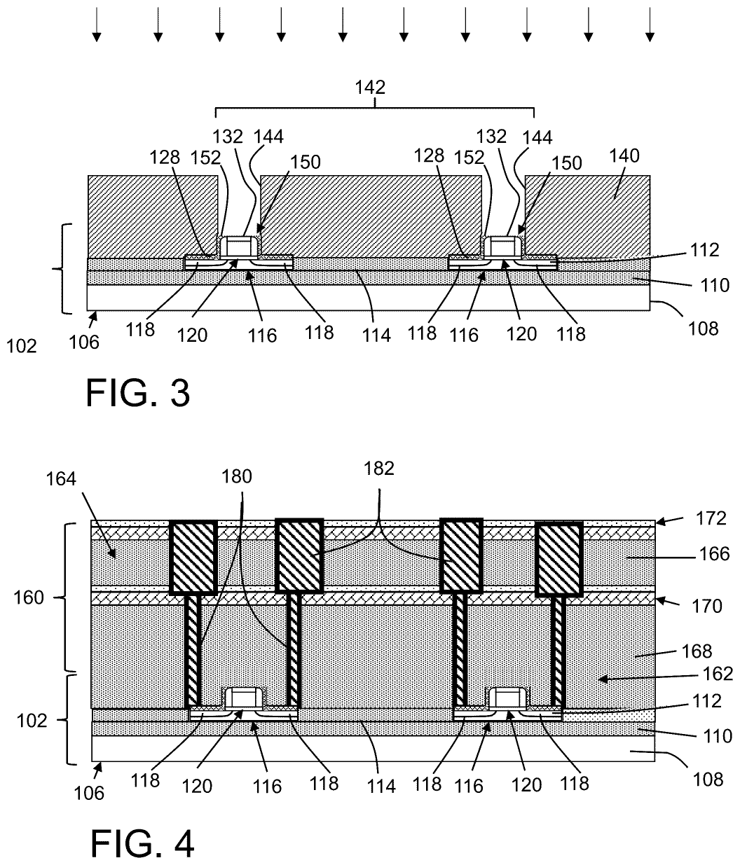

FIG. 3 shows using first mask 140 having air gap pattern 142 to remove etch stop layer 130 over gate body 122 of gate 120 of transistor 116. The removal may include any appropriate etching chemistry for the material of etch stop layer 130, such as but not limited to a reactive ion etch (RIE). Etching generally refers to the removal of material from a substrate (or structures formed on the substrate) and is often performed with a mask in place so that material may selectively be removed from certain areas of the substrate, while leaving the material unaffected, in other areas of the substrate. There are generally two categories of etching, (i) wet etch, and (ii) dry etch. Wet etch is performed with a solvent (such as an acid or a base) which may be chosen for its ability to selectively dissolve a given material (such as oxide), while, leaving another material (such as polysilicon or nitride) relatively intact. This ability to selectively etch given materials is fundamental to many semiconductor fabrication processes. A wet etch will generally etch a homogeneous material (e.g., oxide) isotopically, but a wet etch may also etch single-crystal materials (e.g., silicon wafers) anisotopically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotopic. Ion milling, or sputter etching, bombards the wafer with energetic ions of noble gases which approach the wafer approximately from one direction, and therefore this process is highly anisotopic. Reactive-ion etching (RIE) operates under conditions intermediate between sputter and plasma etching and may be used to produce deep, narrow features, such as trenches for trench isolations. As shown in FIG. 3, etch stop layer 130 remains over S/D regions 118 of transistor 116. As shown in FIG. 3 (see also FIG. 11), the etching may result in gate 120 including a coplanar upper surface 150 defined by silicide upper surface 132 and end surfaces 152 of etch stop layer 130. In some cases, end surfaces (not labeled) of sidewall spacer 124 (FIG. 2) may also be exposed and part of coplanar upper surface 150.

FIG. 4 shows forming an interconnect layer 160 over transistor 116. Preceding this process, first mask 140 may be removed using any now known or later developed removal process appropriate for the mask material, e.g., a wet etch for hard nitride mask or an ashing process (oxygen dry strip process) for a soft resist-based mask. Interconnect layer 160, as described herein, may include a number of layers including a contact or local interconnect layer 162 (commonly referred to as a contact area (CA) layer) and a first metal layer 164. Other interconnect layers, as known in the art, may be formed over interconnect layer 160. Each layer 162, 164 may include a dielectric layer 166, 168, respectively. Of note, interconnect layer 160 includes dielectric layer 168 over transistor 116. Dielectric layers 166, 168 may include an interlayer dielectric material such as but not limited to: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), other low dielectric constant (<3.9) material, or layers thereof. Each layer 162, 164 may also include a respective cap layer 170, 172 at an upper surface thereof. Each cap layer 170, 172 may include one or more layers (not separately labeled) of, for example, a silicon oxide layer and an etch stop layer, formed from silicon nitride (nitride), silicon carbo nitride (SiCN), etc., as known in the art. As understood, various other forms of cap layers may also be employed. Further, it is emphasized that while cap layers 170, 172 are illustrated as identical, they can be different materials, thicknesses, etc.

Any number of contacts 180 may extend through dielectric layer 168 of contact or local interconnect layer 162 (hereafter “local interconnect layer 162”) to various parts of device layer 102. In the example shown, contacts 180 extend to source/drain regions 118 of transistors 116. Other contacts (not shown) may extent to gate 120. As understood, each contact 180 may include a conductor such as aluminum or copper, within a refractory metal liner of ruthenium; however, other refractory metals such as tantalum (Ta), titanium (Ti), tungsten (W), iridium (Ir), rhodium (Rh) and platinum (Pt), etc., or mixtures of thereof, may also be employed. Typically, contacts 180 extend mostly vertically within the semiconductor device to connect conductors in layers thereof, i.e., vertically on page as illustrated. First metal layer 164 may include a number of metal wires 182 therein. Each metal wire 182 may use the same materials as listed for contacts 180. In contrast to contacts 180, metal wires 182 extend mostly horizontally or laterally in a layer within the semiconductor device to connect contacts 180 therein, i.e., into, out of, or across a page as illustrated. In this manner, first metal layer 164 may include a metal wire 182 extending laterally parallel to transistor gate 120 in device layer 102, i.e., vertically above but parallel to transistor gate 120. Interconnect layer 160 can be formed using any now known or later developed semiconductor fabrication techniques, e.g., material deposition, photolithographic patterning and etching, planarization, etc. Although contacts 180 and wires 182 are shown in FIG. 4 as single damascene levels, they could be formed using dual damascene levels containing refractory metal lined copper or tungsten, as known in the art.

“Depositing” or “deposition,” as used herein, may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. Other steps of forming interconnect layer 104 over transistor 116 including etch stop layer 130 over source/drain regions 118 of transistor 116 but not over gate body 122 of gate 120 may also be possible, and are considered within the scope of the disclosure.

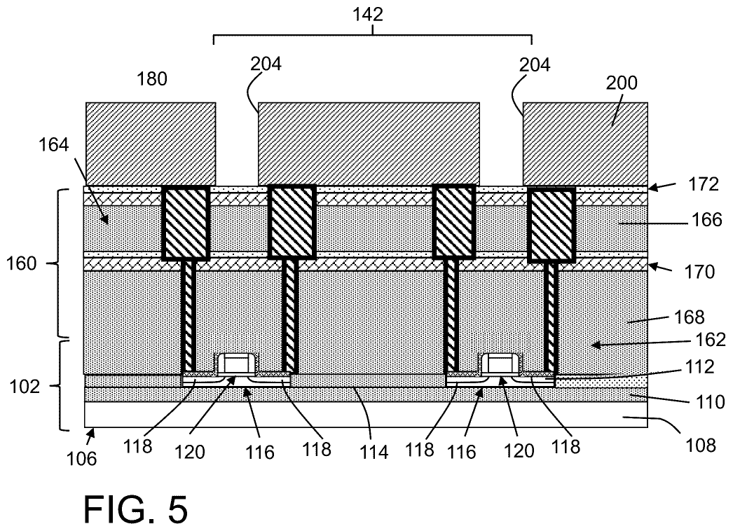

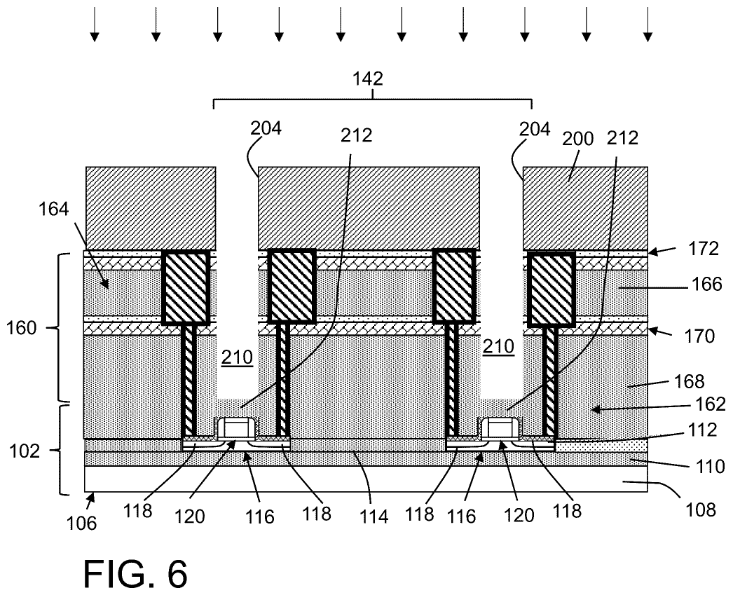

FIGS. 5-6 show forming opening 210 (FIG. 6) into dielectric layer 168, leaving a portion 212 of dielectric layer 168 over gate body 122. More particularly, FIGS. 5-6 show, using a second mask 200 having air gap pattern 142, forming opening 210 (FIG. 6) into dielectric layer 168 over transistor 116, leaving portion 212 of dielectric layer 168 over gate body 122. FIG. 5 shows forming second mask 200 having air gap pattern 142. Air gap pattern 142 may include openings 204 with a pattern to form air gaps where desired. Air gap pattern 142 in FIG. 5 is substantially identical to air gap pattern 142 in first mask 140 FIG. 1. “Substantially identical,” as used in this context, means the pattern of openings 144 (FIG. 1) and 204 (FIG. 5) are identical in an area in which air gaps are to be formed within any fabrication tolerances. Second mask 200 is patterned and etched in a conventional fashion to create openings 204 therein. Second mask 200 may be formed, for example, post first metal layer 164 damascene planarization, e.g., via chemical mechanical polishing (CMP), and may include any now known or later developed masking material.

FIG. 6 show etching an opening 210 partially through interconnect layer 160 using second mask 200 above transistor gate 120. pening 210 exposes sidewalls of dielectric layers 166, 168 of interconnect layer 160. Opening 210 does not extend to gate 120 but leaves a portion 212 over gate body 122 (FIG. 2). In FIG. 6, the etching (indicated by arrows) may include a RIE. Opening 210 is “above the transistor gate,” meaning opening 210 and/or any air gap formed therewith, overlaps transistor gate 120 in any fashion. With regard to opening 210 depth, etching is stopped before it removes portion 212 of dielectric layer 168. That is, the etching does not expose silicide layer 128 by not extending through dielectric layer 168 above gate 120. The etching is controlled to select the depth of opening 210, e.g., through etching strength, duration, etc.

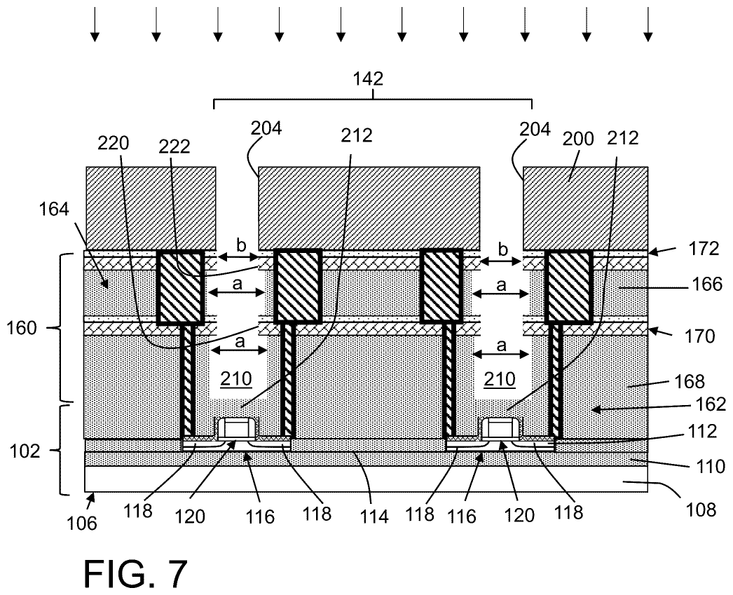

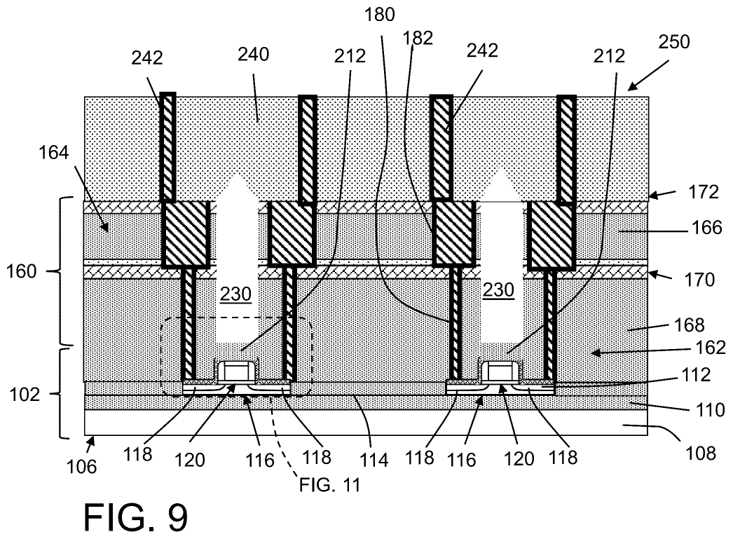

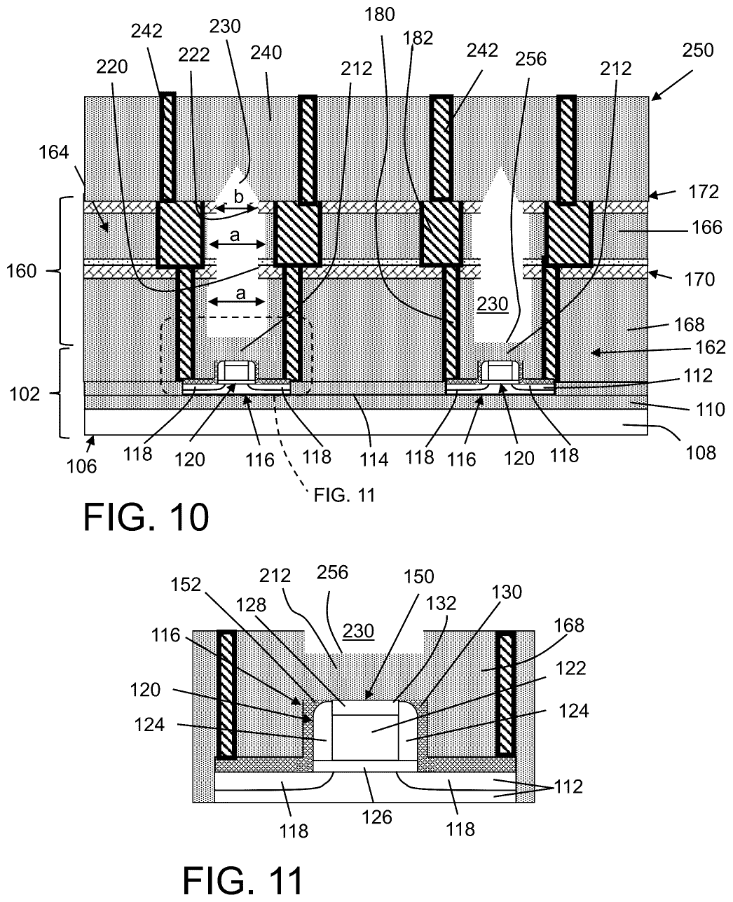

In an optional process, as shown in FIG. 7, a recessing of exposed sidewalls of dielectric layers 166, 168 of interconnect layer 160 in opening 210 can be performed, i.e., prior to forming a cavity 230 (FIGS. 9-10). That is, the exposed sidewalls can be laterally etched. Among other benefits, recessing sidewalls of opening 210 acts to enlarge opening 210 and thus cavities 230 (FIGS. 9-10), reducing the effective dielectric constant of interconnect layer 160 while leaving the cavity top opening to be sealed in the next process step narrower than the cavity itself. If silicon oxide films are used for local interconnect 162 and first metal layers 164 and silicon nitride is used for cap layer(s) 170, 172, then a hydrofluoric acid (HF) wet etch could be used for this recessing process (indicated by arrows). HF concentrations could be in the range of 10:1 to 500:1 dilution with water, as known in the art. Because dielectric materials of layers 166 and 168 etch faster than the dielectric of cap layer(s) 170, 172, FIG. 7 shows that opening widths ‘a’ are wider than opening width ‘b’. The recessing may include, for example, a wet etch as described elsewhere herein. In one embodiment, shown in FIG. 7, recessing exposed sidewalls of dielectric layers 166, 168 of interconnect layer 160 in opening 210 may expose an edge 220, 222 of at least one of the local interconnect cap layer 170 and first metal cap layer 172, respectively, in opening 210. As will be described, edges 222 of first metal cap layer 172 may assist in closing opening 210 to form a cavity, e.g., by facilitating the pinching off of opening 210.

Recessing at this stage can also be used to further deepen opening 210. Assuming, for example, recessing occurred after second mask 200 removal in FIG. 6, but with portion 212 dielectric layer 168 remaining above transistor gate 120, the recessing can further deepen opening 210 to any desired depth so long as portion 212 remains over gate body 122 (FIG. 2).

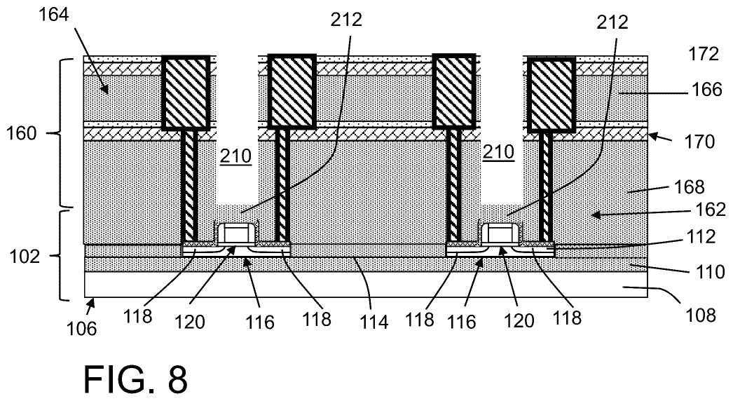

FIG. 8 shows the structure after removing second mask 200 (for the FIG. 6 embodiment only). Second mask 200 may be removed using any now known or later developed removal process appropriate for the mask material, e.g., a wet etch for hard nitride mask or an ashing process (oxygen dry strip process) for a soft resist-based mask.

FIGS. 9 and 10 show forming a cavity 230 over gate 120 by depositing a capping layer 240 to seal opening 210 (FIGS. 6-8) at a surface of interconnect layer 160. FIG. 9 shows cavity 230 relative to the FIG. 6 embodiment, and FIG. 10 shows cavity 230 relative to the FIG. 7 embodiment. As shown, cavity 230 is vertically aligned with gate 120, although perfect alignment is not necessary in all cases. Capping layer 240 may include any dielectric material capable of sealing opening 210 and acting as an ILD for a first via layer to be formed therein. In one embodiment, capping layer 240 may include chemical vapor deposited (CVD) dielectric. In another embodiment, capping layer 240 may include a plasma-enhanced chemical vapor deposition (PECVD) silane oxide. PECVD silane oxide may be chosen because it has very poor step coverage, resulting in a larger cavity volume. In other embodiments, capping layer 240 may include a thin silicon nitride layer with an ILD oxide, such as a PECVD TEOS-based, PVD, or similar oxide (individual layers not shown for clarity). As shown, for example, in FIG. 10, edges 222 of first metal cap layer 172 of first metal layer 164 may act to pinch opening 210 (FIGS. 6-8) to assist in closing cavity 230. Cavity 230 is a sealed cavity and may include a gas, such as air or an inert gas, or a vacuum therein. Cavity 230 does not expose any contact 180 or metal wire 182, i.e., dielectric layers 166, 168 of interconnect layer 160 about cavity 230 cover any conductive wire 182 in first metal layer 164 or any conductive contact 180 in local interconnect layer 162. Cavity 230 may have any lateral layout of opening 210, as described herein. Vias 242 to another metal layer (not shown) may be formed in capping layer 240, using any conventional or later developed technique.

FIG. 11 shows an enlarged view of transistor 116 from the dashed boxes in FIGS. 9 and 10. (Note, a width of cavity 230 shown in FIG. 11 is from FIG. 9—as described, cavity 230 could be wider than shown in FIG. 11 if it were from the FIG. 10 embodiment).

Referring to FIGS. 9-10, a semiconductor device 250 according to embodiments of the disclosure is also shown. In one embodiment, as shown in FIG. 11, semiconductor device 250 may include transistor 116 including S/D regions 118 and gate 120 in device layer 102 (FIG. 9-10). Transistor 116 can take the form of any now known or later developed complementary metal-oxide semiconductor (CMOS) field effect transistor (FET). Gate 120 may include gate body 122 and sidewall spacer 124 adjacent gate body 122. Gate 120 may also include silicide layer 128 over gate body 122, creating silicide upper surface 132. Semiconductor device 250 also includes etch stop layer 130 over S/D regions 118 but not over gate body 122, i.e., as described herein, etch stop layer 130 is removed over gate body 122. Etch stop layer 130 is laterally adjacent sidewall spacer 124. Gate 120 includes an upper surface 150 (which may be a coplanar upper surface 150) defined by silicide upper surface 132 and end surfaces 152 of etch stop layer 130. End surfaces 152 of etch stop layer 130 directly contact portion 212 of dielectric layer 168. As will be recognized, in some cases (not shown), end surfaces of the sidewall spacer 124 may also be part of coplanar upper surface 150.

Semiconductor device 250 can also include interconnect layer 160 over transistor 116. Interconnect layer 160 may include one or more interconnect layers, for example, local interconnect layer 162 and first metal layer 164. Interconnect layer 160 can also include additional layers, not shown. In any event, interconnect layer 160 includes dielectric layer 168 over transistor 116. Silicide layer 128 and end surfaces 254 of etch stop layer 130 directly contact portion 212 of dielectric layer 168.

Semiconductor device 250 also includes cavity 230 extending partially through interconnect layer 160 above gate 120. Cavity 230 is a sealed cavity and may include a gas (e.g., air or an inert gas) or a vacuum therein. Portion 212 of dielectric layer 168 is over gate body 122 and defines a lower surface or bottom 256 of cavity 230. More particularly, bottom 256 of cavity 230 is defined by portion 212 of dielectric layer 168 and is parallel to coplanar upper surface 150 (FIG. 11) of gate 120. Hence, portion 212 of dielectric layer 168 (which is for a zero via (V0) layer of semiconductor device 250) provides lower surface or bottom 256 of cavity 230 and is in direct contact with gate body 122 and end surfaces 152 of etch stop layer 130. Dielectric layer 168 is never entirely removed from over gate 120. Hence, dielectric layer 168 is continuous within interconnect layer 160-including portion 212 of dielectric layer 168 over gate body 122. That is, dielectric layer 168 is devoid of seams or other discontinuities within interconnect layer 160 that would be present where dielectric layer 168 is entirely removed over gate body 122 and another dielectric, such as dielectric capping layer 240, is formed over gate body 122. The combination of removing etch stop layer 130 over gate body 122 and retaining portion 212 of dielectric layer 168 intact results in better performance compared to previous cavity forming techniques that use a single etching step to form the opening for the cavity and either leave the etch stop layer over the gate body, leave some original dielectric over the etch stop layer, or remove the etch stop layer and then form another dielectric layer (with discontinuities with the original dielectric layer) over the gate body.

Dielectric layers 166, 168 of interconnect layer 160 about cavity 230 cover any conductor, e.g., any conductive wire 182 in first metal layer 164 or any conductive contact 180 in local interconnect layer 162. As shown in FIG. 10, edges 220 and/or 222 of at least one of local interconnect cap layer(s) 170 and first metal cap layer(s) 172 may extend into cavity 230. As shown in FIG. 10, first metal layer 164 includes a first metal cap layer 172 at an upper surface thereof. First metal cap layer 172 can have a width ‘b’ in cavity 230 (where opening 210 is positioned in FIG. 7) that is less than a width ‘a’ of cavity 230 (where opening 210 is positioned in FIG. 7) in dielectric layer 166 of first metal layer 164 below first metal cap layer 172. As such, edges 222 of first metal cap layer 164 act to pinch off dielectric layer 166, allowing for a lesser amount of dielectric capping layer 240 to seal opening 210.

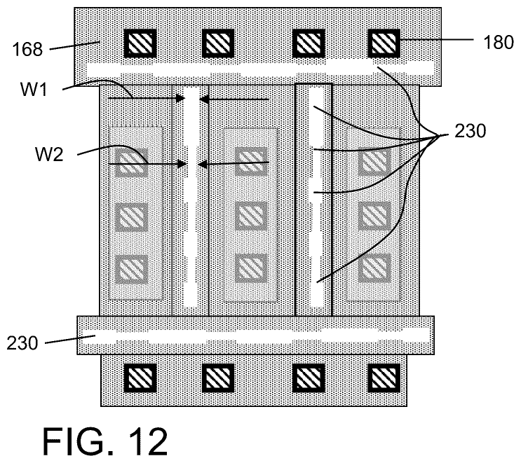

FIG. 12 shows a top-down view of one illustrative cavity layout in a lateral direction. It will be understood that cavities 230 can take a variety of laterally elongated forms. For example, openings 210 may be etched as laterally elongate openings above transistor gate 120. That is, rather than simple vertical openings, openings 210 have a length, e.g., just short of a transistor gate 120 that they parallel. In one example, a portion of cavity 230 can be arranged in a laterally disposed T-shape, i.e., in a T-shape laid out horizontally into and out of the page. In other example, cavity 230 can have varying widths W1, W2 along a length thereof. In any event, cavities 230 do not expose contacts 180 (FIGS. 9-10) or metal wires 182 (FIGS. 9-10), i.e., some of dielectric layer 166, 168 (FIGS. 6-7) remains between contacts 180 and wires 182 and openings 210. Cavities 230 partially through interconnect layer 160 may also be formed such that they are narrower adjacent to contacts 180 to reduce the likelihood of contact 180 intersecting cavity 230. The variable width can occur in local interconnect layer 162 and/or first metal layer 164 and/or subsequent interconnect layers (not shown).

As will be recognized, semiconductor device 250 can be used to form a variety of devices such as a radio frequency semiconductor-on-insulator (RFSOI) switch, a low amplitude amplifier, a power amplifier, etc. In an RFSOI switch embodiment, transistor 116 includes source/drain regions 118 in a semiconductor-on-insulator (SOI) layer 112 of an SOI substrate 106 and gate 120 over SOI layer 112 with gate 120 having gate body 122.

Embodiments of the disclosure provide various technical and commercial advantages, examples of which are discussed herein. Use of cavity 230 over transistor gate 120 according to the various embodiments of the disclosure provides a mechanism to reduce off-capacitance and on-resistance of any device using it by controlling one of the main contributors of intrinsic FET capacitance: the effective dielectric constant of local interconnect layer 162 and first metal layer 164.

In the structures and method described above, a semiconductor material refers to a material whose conducting properties can be altered by doping with an impurity. Semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed.

The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor device, comprising:
a substrate;
a transistor including source/drain regions in the substrate and a gate, the gate having a gate body;
an etch stop layer over the source/drain regions but not over the gate body;
an interconnect layer over the transistor, the interconnect layer including a dielectric layer; and
a cavity extending partially through the interconnect layer above the gate,
wherein a portion of the dielectric layer is over the gate body and defines a bottom of the cavity.

2. The semiconductor device of claim 1, wherein the dielectric layer is continuous within the interconnect layer including the portion of the dielectric layer over the gate body.

3. The semiconductor device of claim 1, wherein the dielectric layer is devoid of seams within the interconnect layer.

4. The semiconductor device of claim 1, wherein the gate further includes a sidewall spacer adjacent the gate body, and the gate body includes a silicide upper surface, wherein the etch stop layer is laterally adjacent to the sidewall spacer, and wherein the gate includes an upper surface defined by the silicide upper surface and end surfaces of the sidewall spacer and end surfaces the etch stop layer.

5. The semiconductor device of claim 4, wherein the end surfaces of the etch stop layer directly contact the portion of the dielectric layer.

6. The semiconductor device of claim 4, wherein a lower surface of the cavity defined by the portion of the dielectric layer is parallel to the coplanar upper surface of the gate.

7. The semiconductor device of claim 1, wherein the interconnect layer includes a local interconnect layer over the transistor and a first metal layer over the local interconnect layer, and the dielectric layer of the interconnect layer about the cavity covers any conductive wire in the first metal layer or any conductive via in the local interconnect layer.

8. The semiconductor device of claim 7, wherein the first metal layer includes a first metal cap layer at an upper surface thereof, and wherein a width of the cavity in the first metal cap layer is less than a width of the cavity in a dielectric layer of the first metal layer below the first metal cap layer.

9. The semiconductor device of claim 1, wherein the cavity includes one of a gas and a vacuum therein.

10. A radio frequency semiconductor-on-insulator (RFSOI) switch, comprising:
a transistor including source/drain regions in a semiconductor-on-insulator (SOI) layer of an SOI substrate and a gate over the SOI layer, the gate having a gate body;
an etch stop layer over the source/drain regions but not over the gate body;
an interconnect layer over the transistor, the interconnect layer including a dielectric layer; and
an air gap extending partially through the interconnect layer above the gate,
wherein a portion of the dielectric layer is over the gate body and defines a bottom of the air gap.

11. The RFSOI switch of claim 10, wherein the dielectric layer is continuous within the interconnect layer including the at least a portion of the dielectric layer over the gate body.

12. The RFSOI switch of claim 10, wherein the dielectric layer is devoid of seams within the interconnect layer.

13. The RFSOI switch of claim 10, wherein the gate further includes a sidewall spacer adjacent the gate body, and the gate body includes a silicide upper surface, wherein the etch stop layer is laterally adjacent to the sidewall spacer, and wherein the gate includes a coplanar upper surface defined by the silicide upper surface and end surfaces of the sidewall spacer and end surfaces the etch stop layer.

14. The RFSOI switch of claim 13, wherein the end surfaces of the etch stop layer directly contact the portion of the dielectric layer.

15. The RFSOI switch of claim 13, wherein a lower surface of the air gap defined by the portion of the dielectric layer is parallel to the coplanar upper surface of the gate.

16. The RFSOI switch of claim 10, wherein the interconnect layer includes a local interconnect layer over the transistor and a first metal layer over the local interconnect layer, and the dielectric layer of the interconnect layer about the air gap covers any conductive wire in the first metal layer or any conductive via in the local interconnect layer.

17. The RFSOI switch of claim 16, wherein the first metal layer includes a first metal cap layer, and wherein a width of the air gap in the first metal cap layer is less than a width of the air gap in a dielectric layer of the first metal layer below the first metal cap layer.

18. The RFSOI switch of claim 10, wherein the air gap is laterally elongated.

19. A method of forming a cavity for a semiconductor device, the method comprising:
forming an interconnect layer over a transistor including an etch stop layer over source/drain regions of the transistor but not over a gate body of a gate of the transistor, the interconnect layer including a dielectric layer over the transistor; and
forming an opening into the dielectric layer, leaving a portion of the dielectric layer over the gate body; and
forming a cavity over the gate by depositing a capping layer to seal the opening.

20. The method of claim 19. further comprising recessing exposed sidewalls of the dielectric layer of the interconnect layer in the opening prior to forming the cavity.
